(19) United States
(12) Patent Application Publication
(10) Pub. No.: US 2012/0105779 A1
(43) Pub. Date: May 3, 2012

(54) COLOR FILTER SUBSTRATE, METHOD OF MANUFACTURING THEREOF AND 3D LIQUID CRYSTAL DISPLAY

(75) Inventor: Heecheol KIM, Beijing (CN)

(73) Assignee: BOE TECHNOLOGY GROUP CO., LTD., Beijing (CN)

(21) Appl. No.: 13/284,235

(22) Filed: Oct. 28, 2011

(30) Foreign Application Priority Data
Oct. 29, 2010 (CN) 201010532015.4

(51) Int. Cl. G02F 1/1335; G03F 1/00

(52) U.S. Cl. 349/106; 430/7

(57) ABSTRACT

An embodiment of the disclosed technology provides a color filter substrate with a plurality of pixel units, comprising: a base substrate, a patterned phase retarder film disposed at a first side of the base substrate, and each of phase retarders of the patterned phase retarder film respectively corresponds to each of pixel units; and a first black matrix disposed between the base substrate and the patterned phase retarder film, where each portion of the first black matrix corresponds to a border of two adjacent phase retarders.

### BACKGROUND

Embodiments of the disclosed technology relate to a color filter substrate, a method of manufacturing thereof, and a three dimension (3D) liquid crystal display.

At present, liquid crystal displays have become a commonly used kind of flat panel displays, and thin film transistor liquid crystal displays (TFT-LCDs) are the main type of LCDs. 3D display is one important development trend in LCD fields and can be achieved based on a plurality of displaying principles, and one of the plurality of displaying principles is to achieve 3D display by providing a patterned phase retarder film.

A liquid crystal panel of a LCD comprises an array substrate and a color filter substrate assembled together with a liquid crystal layer injected therebetween. Polarizers are disposed on both sides of the liquid crystal panel and images are displayed by using the optical rotation property of liquid crystal molecules. In order to achieve 3D display, a patterned phase retarder film is provided on the display side of the liquid crystal panel, and each of phase retarders in the patterned phase retarder film is respectively disposed to correspond to one of pixel units. The phase retarders can be divided into two types, i.e., left eye phase retarders and right eye phase retarders, that have different polarization properties, and the two types of phase retarders are alternatively disposed to correspond to pixel units. In cooperation with a pair of polarization spectacles, the left eye of a viewer can watch images only displayed in a part of the pixel units via the left eye phase retarders, and the right eye of the viewer can watch images only displayed in the remaining pixel units via the right eye phase retarders. An image watched by the left eye and a corresponding image watched by the right eye are combined in the viewer's brain to form a stereoscopic image, as shown in FIG. 1, which is a schematic principle view for this type of 3D display or imaging.

However, in a current 3D display by using the patterned phase retarder film, viewing angles are relatively small. FIG. 2 is a partial cross-sectional side view of a color filter substrate in the current 3D liquid crystal display, showing on pixel unit for example. A color filter (not shown) and a black matrix 2 are disposed at one side, facing an array substrate, of a base substrate 1 of the color filter substrate. The color filter is disposed to correspond to the pixel unit, and the black matrix 2 is disposed between two adjacent pixel units. A polarizer 4 and a patterned phase retarder film 5 are adhered to the base substrate 1 at the other side of the base substrate 1, facing away from the array substrate, via an adhesive layer 3. Phase retarders each having a block shape of the patterned phase retarder film 5 are arranged in a matrix form corresponding to the pixel units across the color filter substrate, and left eye phase retarders are adjacent to right eye phase retarders. Arrows shown in FIG. 2 denote viewing light paths (that is, the converse light paths of emitting light), and it can be seen that a portion of light transmitting through the pixel unit is blocked by the black matrix 2 and a portion thereof is emitted after passing through the color filter. However, because the adhesive layer 3, the polarizer 4 and the like are disposed between the patterned phase retarder film 5 and the black matrix 2, a distance from the patterned phase retarder film 5 to the black matrix 2 is generally up to 0.5 mm-0.7 mm, which causes light at relatively large tilt angles to escape from the phase retarder corresponding to the pixel unit and brings about a crosstalk. That is to say, viewing angles which make 3D images to be normally displayed is generally within a range of 2°-8° deviated from a normal direction of the surface of the liquid crystal panel, and a relatively large tilt angle generally larger than 10° will cause improper 3D image display.

### SUMMARY

An embodiment of the disclosed technology provides a color filter substrate with a plurality of pixel units, comprising: a base substrate, a patterned phase retarder film disposed at a first side of the base substrate, and each of phase retarders of the patterned phase retarder film respectively corresponds to each of pixel units; and a first black matrix disposed between the base substrate and the patterned phase retarder film, where each portion of the first black matrix corresponds to a border of two adjacent phase retarders.

Further an embodiment of the disclosed technology further provides a method of manufacturing a color filter substrate with a plurality of pixel units, comprising: forming a first black matrix at a first side of a base substrate; forming a patterned phase retarder film on the first black matrix, wherein each of phase retarders of the patterned phase retarder film respectively corresponds to each of pixel units and each portion of the first black matrix corresponds to a border of two adjacent phase retarders.

Still further an embodiment of the disclosed technology further provides a three-dimension (3D) liquid crystal display, comprising an external frame and a liquid crystal panel, wherein the liquid crystal panel comprises an array substrate and a color filter substrate according to an embodiment of the disclosed technology with a liquid crystal layer interposed therebetween.

Further scope of applicability of the disclosed technology will become apparent from the detailed description given hereinafter. However, it should be understood that the detailed description and specific examples, while indicating preferred embodiments of the disclosed technology, are given by way of illustration only, since various changes and modifications within the spirit and scope of the disclosed technology will become apparent to those skilled in the art from the following detailed description.

### BRIEF DESCRIPTION OF THE DRAWINGS

The disclosed technology will become more fully understood from the detailed description given hereinafter and the accompanying drawings which are given by way of illustration only, and thus are not limitative of the disclosed technology and wherein:

FIG. 1 is a schematic view for showing a imaging principle of a current 3D liquid crystal display;

FIG. 2 is a partial cross-sectional side view of a color filter substrate in the current 3D liquid crystal display;

FIG. 3 is a schematic structural view of a color filter substrate according to a first embodiment of the disclosed technology;

FIG. 4 is a schematic structural view of a color filter substrate according to a second embodiment of the disclosed technology;

FIG. 5 is a principle view for showing viewing light paths in the color filter substrate according to the second embodiment of the disclosed technology; and

FIG. 6-8 are schematic views for showing a process of manufacturing a color filter substrate according to a fourth embodiment of the disclosed technology.

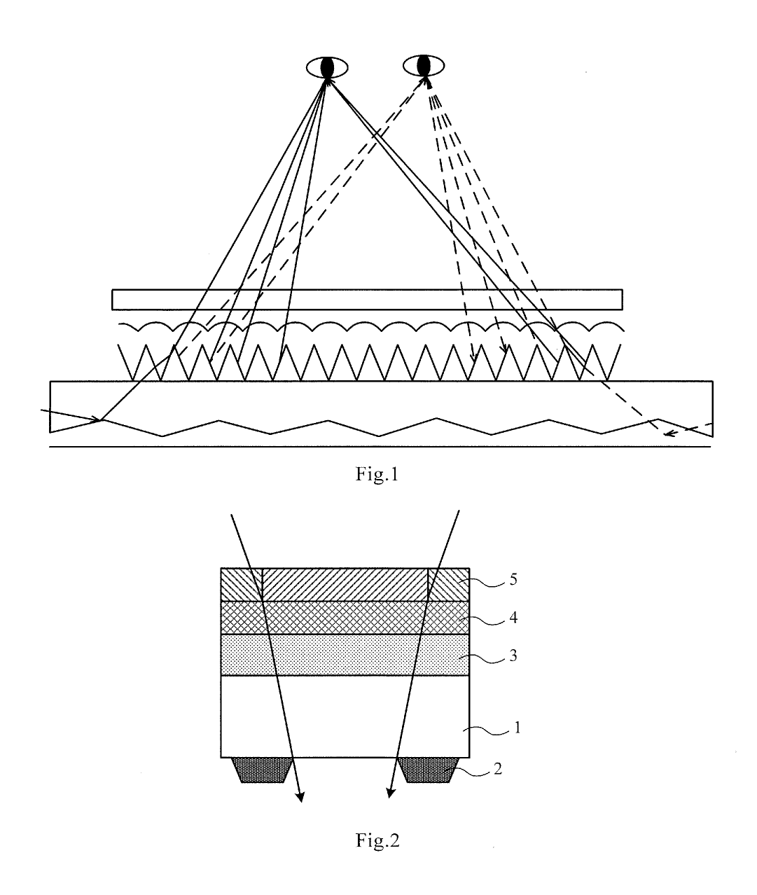

### DETAILED DESCRIPTION

Embodiments of the disclosed technology being thus described, it will be obvious that the same may be varied in many ways. Such variations are not to be regarded as a departure from the spirit and scope of the disclosed technology, and all such modifications as would be obvious to those skilled in the art are intended to be included within the scope of the following claims.

### First Embodiment

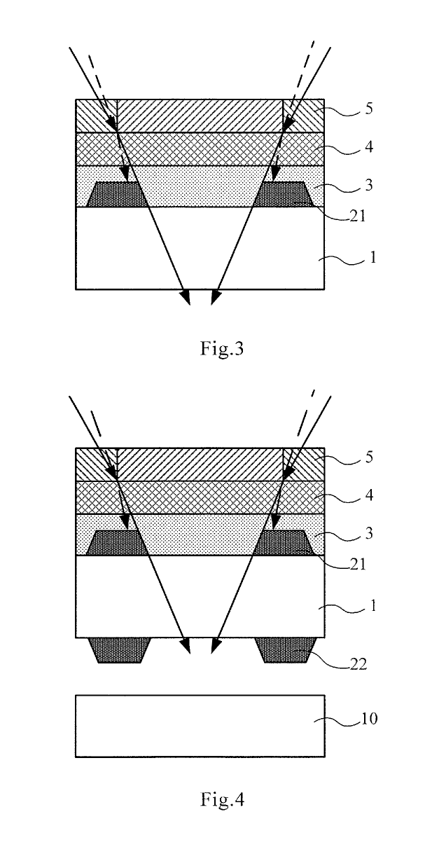

FIG. 3 is a schematic structural view of a color filter substrate according to a first embodiment of the disclosed technology. The color filter substrate has a plurality of pixel units and comprises a base substrate 1 and a patterned phase retarder film 5 disposed at a side of the base substrate 1 facing away from an array substrate if the color filter substrate is assembled with the array substrate. The patterned phase retarder film 5 comprises a plurality of phase retarders arranged in an array form. Each of the plurality of phase retarders of the patterned phase retarder film 5 respectively corresponds to one of the plurality of pixel units for separately displaying an image for the right eye or the left eye of a viewer. A first black matrix 21 is disposed between the base substrate 1 and the patterned phase retarder film 5 and corresponding to each pixel unit, and each portion of the first black matrix 21 is disposed to correspond to a border between two adjacent phase retarders. The color filter substrate of this embodiment further comprises color filters corresponding to the pixel units (but not shown in the drawings for simplicity), and the color filter can be provided on the same side of the base substrate as the first black matrix 21 or on the opposite side.

The technical solution of the present embodiment is applicable to a liquid crystal display which achieves 3D display by using the patterned phase retarder film 5. As shown in FIG. 3, the first black matrix 21 is disposed on the outer side of the base substrate 1 and at the same side as the patterned phase retarder film 5. Therefore, as compared with a technical solution in which a black matrix and a patterned phase retarder film are positioned at difference sides of a base substrate, the black matrix 21 is closer to the patterned phase retarder film 5. Generally, a polarizer 4, an adhesive layer 3 (e.g., pressure-sensitive adhesive layer) and other films may be disposed between the patterned phase retarder film 5 and the base substrate 1, and the black matrix 21 may be directly formed on the base substrate 1 or another film on the base substrate 1.

The technical solution of the present embodiment can improve the viewing angle properties and increase the viewing range for display. More specifically, as shown in FIGS. 2 and 3, borders of each of the phase retarders are not consistent with borders of the corresponding black matrix, and thus, light for displaying an image in one pixel unit may be emitted from a phase retarder for an adjacent pixel unit to the pixel unit, and a image crosstalk may occurs during 3D display. In this case, the black matrix can block a part of the light which causes image crosstalk. By taking viewing light of a viewer's as an example, in comparing viewing light paths in FIG. 3 with viewing light paths in FIG. 2, viewing light having a small angle can be transmitted into the color filter substrate in FIG. 2, that is, a crosstalk can occur between two adjacent pixel units in FIG. 2; however, the viewing light having the same small angle can be blocked by the black matrix in FIG. 3, and therefore, in the FIG. 3, an angle of the light, which is emitted from a phase retarder corresponding to adjacent pixel unit and thus causes a crosstalk, increases, that is, an incident angle of light which would not cause crosstalk increases. That is to say, an image can be normally viewed within the range of the above incident angles of the light, and in this range crosstalk does not occur. Therefore, the color filter substrate of the present embodiment can effectively increase the viewing angle range for display.

Although the first black matrix and the phase retarder are provide at a certain distance from each other along a direction perpendicular to the surface of the base substrate and a crosstalk may be caused, a viewing angle property can be significantly improved by reducing the certain distance. In a conventional color filter of a LCD, a distance between the black matrix and the phase retarder film which are respectively disposed on different sides of the base substrate is up to 0.5-0.7 mm, and thus, a crosstalk may occur when a viewing angle deviates 10° or more. In the present embodiment, preferably the distance between the first black matrix 21 and the phase retarder 5 may be set to 0.1 mm-0.2 mm in order to obtain an excellent viewing angle range, and as a result, even in a case in which a viewing angle deviates 10° or more, a crosstalk would not occur.

### Second Embodiment

FIG. 4 is a schematic structural view of a color filter substrate according to a second embodiment of the disclosed technology, wherein an array substrate 10 is also shown. The present embodiment may be on the basis of the first embodiment, and a difference between the second embodiment and the first embodiment lies in that a second black matrix 22 is further at the side of the base substrate 1 facing the array substrate 10, that is, the second black matrix 22 is disposed at the inner side of the base substrate 1 facing the array substrate 10. A liquid crystal layer (not shown) is interposed between the array substrate 10 and the color filter substrate. Similarly, the color filter substrate of this embodiment further comprises color filters corresponding to the pixel units (but not shown in the drawings for simplicity), and the color filter can be provided on the same side of the base substrate as the first black matrix 21 or the second black matrix 22.

In the technical solution of the present embodiment, the first black matrix 21 and the second black matrix 22 are collectively used to block light for one pixel unit from being emitted toward adjacent pixel units. As shown in FIG. 5, the first black matrix 21 and the second black matrix 22 are provided so that the black matrixes 21 and 22 can block light distributed within a relatively broad range.

On the basis of the above mentioned technical solution, each portion of the black matrix 22 is preferably disposed to correspond to the corresponding portion of the first black matrix 21, and thus, the black matrix 22 is used not only to block light but also help fabricate the first black matrix 21. The detailed manufacturing process may comprise the following steps. The second black matrix 22 is firstly formed on the base substrate, a black matrix film layer is then formed at the side of the base substrate 1 opposite to the side on which the second black matrix 22 is formed, and then, the black matrix film layer is radiated from the second black matrix 22 side with the second black matrix 22 as a mask for exposing and then developed, thus forming the first black matrix 21 corresponding to the second black matrix 22. The manufacturing process can reduce the amount of patterning process with a mask plate by one, and thus, manufacturing cost can be reduced. Further, the first black matrix 21 and the second black matrix 22 may be completely corresponded to each other, thus the aperture ratio of the pixel units of a liquid crystal display would not be influenced.

### Third Embodiment

A third embodiment of the disclosed technology provides a method of manufacturing a color filter substrate, the method comprises the following steps:

Step 610, forming a first black matrix on a first side of a base substrate facing away from an array substrate if the cooler filter substrate is assembled with the array substrate;

Step 620, forming a patterned phase retarder film on the first black matrix, wherein each phase retarder in the patterned phase retarder film corresponds to each pixel unit and each portion of the first black matrix corresponds to a border between two adjacent phase retarders.

The technical solution of the present embodiment can be used to manufacture a color filter substrate provided by an embodiment of the disclosed technology, and thus, a viewing angle property of a display can be improved by reducing the distance between the black matrix and the phase retarder.

### Fourth Embodiment

A fourth embodiment of the disclosed technology provides a method of manufacturing a color filter substrate, the method further comprises forming a second black matrix at a second side of the base substrate opposite to the first side thereof on the basis of the third embodiment. The manufacturing order of the first black matrix and the second black matrix is not limited, and preferably, the black matrix formed latterly is formed by using the black matrix formed formerly as an exposure mask. For example, after formation of the second black matrix, the first black matrix is formed, and the method of manufacturing the color filter substrate comprises the following steps:

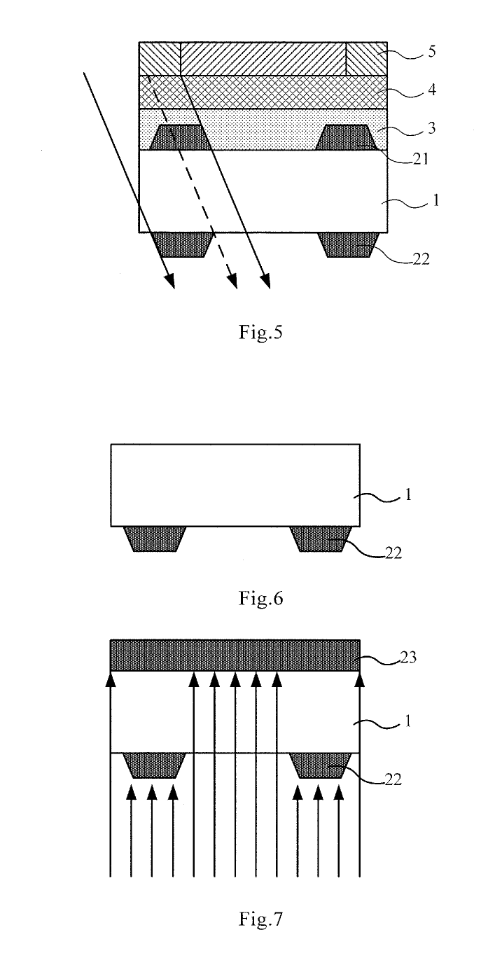

Step 710, forming a second black matrix 22 at a second side of the base substrate 1 opposite to a first side, as shown in FIG. 6;

Step 720, forming a black matrix film layer 23 on the first side of the base substrate 1;

Step 730, radiating the color filter substrate from the second side of the base substrate 1 to expose the black matrix film layer 23 by using the second black matrix 22 as a mask, as shown in FIG. 7; in an example, a positive resin material can be properly selected to form the first black matrix 21 with ultraviolet rays;

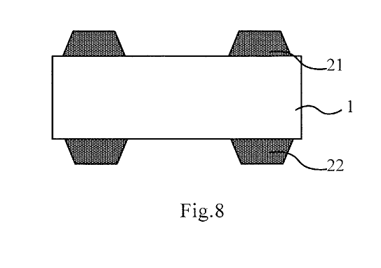

Step 740, developing the exposed black matrix film layer 23 to form the first black matrix 21, as shown in FIG. 8;

Step 750, forming a patterned phase retarder film 5 at the first side of the base substrate 1 on which the first black matrix 21 is formed, wherein each phase retarder of the patterned phase retarder film 5 respectively corresponds to each pixel unit and each portion of the first black matrix 21 corresponds to a border between two adjacent phase retarders, as shown in FIG. 4. In this step, another film layer may be formed before or after a formation of the first black matrix 21, for example, a polarizer 4 may be adhered to the base substrate via an adhesive layer 3 (for example, the pressure-sensitive adhesive layer) after the formation of the first black matrix 21, and then, the patterned phase retarder film 5 is formed on the polarizer 4.

The technical solution of the above embodiment can ensure a complete corresponding relationship between the first black matrix and the second black matrix, and thus, an aperture ratio of the pixel unit of a liquid crystal display can not be influenced.

An embodiment of the disclosed technology further provides a 3D liquid crystal display comprising a external frame and a liquid crystal panel, wherein the liquid crystal panel comprises an array substrate and a color filter substrate provided by an embodiment of the disclosed technology assembled together with a liquid crystal layer interposed therebetween and the liquid crystal panel is fixed inside the external frame.

The 3D liquid crystal display according to the embodiment of the disclosed technology uses a patterned phase retarder film, and by changing a position of a black matrix, a light leakage between the black matrix and the patterned phase retarder film on the color filter substrate is suppressed, and thus, the problem caused by parallax can be solved. In addition, when an image is viewed along an angle deviated upward, downward, leftward or rightward from the right front, 3D mura, pseudoscopic, crosstalk and the like can be alleviated or diminished. A high precise 3D display structure can use other structures other than a patterned phase retarder film, and for example, an excellent 3D effect can be achieved in 3D display structure with BLU driving.

The embodiment of the disclosed technology being thus described, it will be obvious that the same may be varied in many ways. Such variations are not to be regarded as a departure from the spirit and scope of the disclosed technology, and all such modifications as would be obvious to those skilled in the art are intended to be included within the scope of the following claims.

What is claimed is:

1. A color filter substrate with a plurality of pixel units, comprising:
a base substrate,
a patterned phase retarder film disposed at a first side of the base substrate, and each of phase retarders of the patterned phase retarder film respectively corresponds to each of pixel units; and
a first black matrix disposed between the base substrate and the patterned phase retarder film, where each portion of the first black matrix corresponds to a border of two adjacent phase retarders.

2. The color filter substrate according to claim 1, wherein a second black matrix is disposed at a second side of the base substrate opposite to the first side.

3. The color filter substrate according to claim 2, wherein each portion of the second black matrix and each portion of the first black matrix are disposed to correspond to each other.

4. The color filter substrate according to claim 1, wherein a distance between the first black matrix and the phase retarder film is 0.1 mm-0.2 mm.

5. A method of manufacturing a color filter substrate with a plurality of pixel units, comprising:
forming a first black matrix at a first side of a base substrate;
forming a patterned phase retarder film on the first black matrix, wherein each of phase retarders of the patterned phase retarder film respectively corresponds to each of pixel units and each portion of the first black matrix corresponds to a border of two adjacent phase retarders.

6. The method according to claim 5, further comprising:
forming a second black matrix at a second side of the base substrate opposite to the first side.

7. The method according to claim 6, wherein after formation of the second black matrix, the first black matrix is formed, and forming the first black matrix on the base substrate comprises:
forming a black matrix film layer on the first side of the base substrate;
radiating the color filter substrate from the second side of the base substrate to expose the black matrix film layer; and
developing the black matrix film layer to form the first black matrix.

8. A three-dimension (3D) liquid crystal display, comprising:
an external frame, and
a liquid crystal panel, wherein the liquid crystal panel comprises an array substrate and a color filter substrate according to claim 1 with a liquid crystal layer interposed therebetween.
